(19) United States
(12) Patent Application Publication
(10) Pub. No.: US 2026/0190805 A1
(43) Pub. Date: Jul. 2, 2026

(54) DISPLAY DEVICE

(71) Applicant: LG Display Co., Ltd., Seoul (KR)

(72) Inventors: Hyeonhye YU, Paju-si (KR); SeHong PARK, Paju-si (KR); GiBin KIM, Paju-si (KR)

(73) Assignee: LG Display Co., Ltd., Seoul (KR)

(21) Appl. No.: 19/219,910

(22) Filed: May 27, 2025

(30) Foreign Application Priority Data
Dec. 27, 2024 (KR) 10-2024-0198995

(51) Int. Cl. H10K 59/80; H10K 59/122; H10K 59/35

(52) U.S. Cl. CPC H10K 59/879; H10K 59/122; H10K 59/352; H10K 59/8731

(57) ABSTRACT

A display device in some examples can include a substrate having a plurality of subpixels, an insulation layer including a concave portion disposed in the plurality of subpixels and a peripheral portion adjacent to the concave portion, a pixel electrode disposed in the concave portion and the peripheral portion, a bank disposed on the pixel electrode and the insulation layer and having an opening area overlapping at least a portion of the concave portion, an intermediate layer disposed on the opening area of the bank, a common electrode disposed on the intermediate layer, an encapsulation layer disposed on the common electrode, and a notch pattern disposed in an area corresponding to an outer portion of the concave portion and disposed in the bank, thereby enhancing light extraction efficiency.

### CROSS-REFERENCE TO RELATED APPLICATION

This application claims priority to Korean Patent Application No. 10-2024-0198995, filed in the Republic of Korea on Dec. 27, 2024, which is hereby expressly incorporated by reference for all purposes as if fully set forth herein into the present application.

### BACKGROUND

### Field

Embodiments of the disclosure relate to a display device.

### Description of Related Art

As the information society develops, demand for display devices for displaying images is increasing in various forms. Various display devices, such as liquid crystal display devices, plasma display devices, and organic light emitting display devices, are recently being utilized.

The display device uses a method in which light is emitted outward to display images. However, in devices that use this approach, it can be challenging to improve brightness due to issues such as light being trapped inside the device without being extracted to the outside.

### BRIEF SUMMARY OF THE DISCLOSURE

Embodiments of the disclosure can provide a display device capable of enhancing light extraction efficiency.

Embodiments of the disclosure can provide a display device capable of extracting an optical waveguide component by an encapsulation layer by incorporating a light extraction pattern in a non-emission area.

Embodiments of the disclosure can provide a display device capable of enhancing light extraction efficiency by blocking the light propagating to the adjacent subpixel by incorporating a light extraction pattern in a non-emission area.

Embodiments of the disclosure provide an improved display device configured to address the limitations and disadvantages associated with the related art.

Objects of embodiments of the disclosure are not limited to those set forth herein, and other unmentioned objects would be apparent to one of ordinary skill in the art from the following description.

Embodiments of the disclosure can provide a display device comprising a substrate having a plurality of subpixels, an insulation layer including a concave portion disposed in the plurality of subpixels and a peripheral portion surrounding the concave portion, a pixel electrode disposed in the concave portion and the peripheral portion, a bank disposed on the pixel electrode and the insulation layer and having an opening area overlapping at least a portion of the concave portion, an intermediate layer disposed on the opening area of the bank and the bank, a common electrode disposed on the intermediate layer, an encapsulation layer disposed on the common electrode, and a notch pattern disposed in an area corresponding to an outer portion of the concave portion and disposed in the bank.

Embodiments of the disclosure can provide a display device comprising a substrate including a display area including an emission area and a non-display area surrounding the display area, an insulation layer disposed in the display area and including a concave portion and a peripheral portion surrounding the concave portion, a pixel electrode disposed on the insulation layer, a bank having an opening area overlapping at least a portion of the concave portion, an intermediate layer disposed on the pixel electrode and the bank, a common electrode disposed on the intermediate layer, an encapsulation layer disposed on the common electrode, and a notch pattern spaced apart from the opening area of the bank and disposed on the bank along the opening area of the bank.

According to embodiments of the disclosure, there can be provided a display device capable of enhancing light extraction efficiency.

According to embodiments of the disclosure, there can be provided a display device capable of extracting an optical waveguide component by an encapsulation layer by incorporating a light extraction pattern in a non-emission area.

According to embodiments of the disclosure, there can be provided a display device capable of enhancing light extraction efficiency by blocking the light propagating to the adjacent subpixel by incorporating a light extraction pattern in a non-emission area.

According to embodiments of the disclosure, there can be provided a display device capable of low-power consumption by enhancing light extraction efficiency.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a view illustrating an example system configuration of a display device according to embodiments of the disclosure;

FIG. 2 is an example cross-sectional view illustrating a subpixel in a display panel according to embodiments of the disclosure;

FIG. 3 is an example plan view illustrating a layout of a subpixel according to embodiments of the disclosure;

FIGS. 4 to 6 are example cross-sectional views illustrating a display panel taken along line A-B of FIG. 3, according to embodiments of the disclosure;

FIGS. 7 to 11 are example plan views illustrating a subpixel according to embodiments of the disclosure;

FIG. 12 is an example plan view illustrating an emission area of a subpixel according to embodiments of the disclosure;

FIGS. 13 to 16 are example plan views illustrating a principle of light extraction by a display device according to embodiments of the disclosure; and

FIGS. 17 to 19 illustrate examples of simulation results showing a light extraction path for a display device according to embodiments of the disclosure.

### DETAILED DESCRIPTION OF THE EMBODIMENTS

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description can make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various embodiments of the disclosure are described in detail with reference to the accompanying drawings. All the components of each display device according to all embodiments of the disclosure are operatively coupled and configured.

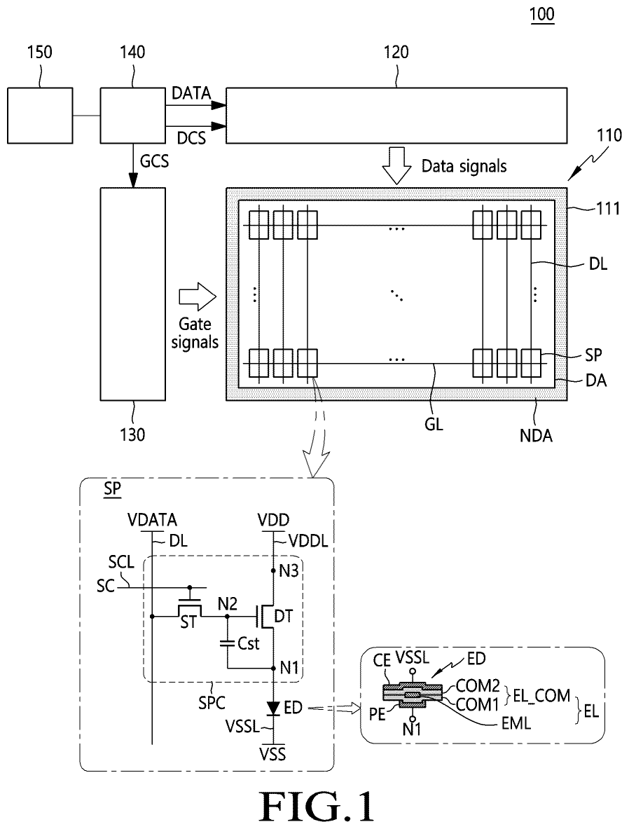

FIG. 1 is a view illustrating an example system configuration of a display device 100 according to embodiments of the disclosure.

Referring to FIG. 1, the display device 100 according to embodiments of the disclosure can include a display panel 110 and display driving circuits, as components for displaying images. The display driving circuits are circuits for driving the display panel 110 and can include a data driving circuit 120, a gate driving circuit 130, and a controller 140.

The display panel 110 can include a substrate 111 and a plurality of subpixels SP disposed on the substrate 111.

The substrate 111 can include a display area DA capable of displaying an image and a non-display area NDA positioned outside the display area DA. The display area DA and the non-display area NDA can be areas of the display panel 110.

The display area DA can also be referred to as an active area, and a plurality of subpixels SP for displaying an image can be disposed in the display area DA. The non-display area NDA can also be referred to as a non-active area and can include a pad area.

In the display panel 110 according to embodiments of the disclosure, the non-display area NDA can be very small. In the disclosure, the non-display area NDA is also referred to as a “bezel.” For example, the non-display area NDA can include a first non-display area positioned outside in the first direction from the display area DA, a second non-display area positioned outside in the second direction from the display area DA, a third non-display area positioned outside in a direction opposite to the first direction from the display area DA, and a fourth non-display area positioned outside in a direction opposite to the second direction from the display area DA.

The first non-display area can include a pad area to which a driving circuit is connected or bonded. The second to fourth non-display areas can have a very small size.

As another example, the boundary area between the display area DA and the non-display area NDA can be bent so that the non-display area NDA can be positioned under the display area DA. In this case, no or little change can be made to the non-display area NDA shown to the user when the user views the display area 100 from the front. For example, the first non-display area can include a bending area. As the bending area is bent, the first non-display area may not be visible from the front.

Various types of signal lines for driving a plurality of subpixels SP can be disposed on the substrate 111 of the display panel 110.

The display device 100 according to embodiments of the disclosure can be a liquid crystal display device or a self-emission display device in which the display panel 110 emits light by itself. When the display device 100 according to the embodiments of the disclosure is a self-emission display device, each of the plurality of subpixels SP can include a light emitting element.

For example, the display device 100 according to embodiments of the disclosure can be an organic light emitting diode display in which the light emitting element is implemented as an organic light emitting diode (OLED). As another example, the display device 100 according to embodiments of the disclosure can be an inorganic light emitting display device in which the light emitting element is implemented as an inorganic material-based light emitting diode. As another example, the display device 100 according to embodiments of the disclosure can be a quantum dot display device in which the light emitting element is implemented as a quantum dot which is self-emission semiconductor crystal.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors.

Referring to FIG. 1, the subpixel SP can include a light emitting element ED and a subpixel circuit unit SPC for driving the light emitting element ED.

Referring to FIG. 1, the subpixel circuit SPC can include a plurality of transistors for driving the light emitting element ED and at least one capacitor. In the disclosure, the subpixel circuit SPC can drive the light emitting element ED by supplying a driving current to the light emitting element ED at a predetermined timing. The light emitting element ED can be driven by a driving current to emit light.

The plurality of transistors can include a driving transistor DT for driving the light emitting element ED and a scan transistor ST that is turned on or off according to the scan signal SC.

The driving transistor DT can supply a driving current to the light emitting element ED.

The scan transistor ST can be configured to control the electrical state of a corresponding node in the subpixel circuit SPC or to control the state or operation of the driving transistor DT.

The at least one capacitor can include a storage capacitor Cst for maintaining a constant voltage during a frame.

To drive the subpixel SP, a data signal VDATA as an image signal and a scan signal SC as a gate signal can be applied to the subpixel SP. Further, for driving the subpixel SP, a common voltage including the first common voltage VDD and the second driving voltage VSS can be applied to the subpixel SP.

The light emitting element ED can include a pixel electrode PE, an intermediate layer EL, and a common electrode CE. The intermediate layer EL can be disposed between the pixel electrode PE and the common electrode CE. For example, the pixel electrode PE can be an electrode disposed in each subpixel SP, and the common electrode CE can be an electrode commonly disposed in all the subpixels SP. For example, the pixel electrode PE can be an anode electrode, and the common electrode CE can be a cathode electrode. As another example, the pixel electrode PE can be a cathode electrode, and the common electrode CE can be an anode electrode. For convenience of description, an example is described in which the pixel electrode PE is an anode electrode, and the common electrode CE is a cathode electrode.

When the light emitting element ED is an organic light emitting element, the intermediate layer EL can include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 can be collectively referred to as a common intermediate layer EL_COM.

The light emitting layer EML can be disposed for each subpixel SP. The common intermediate layer EL_COM can be disposed commonly across a plurality of subpixel SP.

The light emitting layer EML can be disposed for each light emitting area, and the common intermediate layer EL_COM can be commonly disposed over the plurality of light emitting areas and the non-light emitting area.

The light emitting layer EML and the common intermediate layer EL_COM can be commonly disposed over the plurality of subpixels SP.

The light emitting layer EML and the common intermediate layer EL_COM can be commonly disposed across a plurality of emission areas and non-emission areas.

For example, the first common intermediate layer COM1 can include a hole injection layer HIL and a hole transport layer HTL. The second common intermediate layer COM2 can include an electron transport layer ETL and an electron injection layer EIL.

The hole injection layer can inject holes from the pixel electrode PE to the hole transport layer, and the hole transport layer can transport holes to the light emitting layer EML. The electron injection layer can inject electrons from the common electrode CE to the electron transport layer, and the electron transport layer can transport electrons to the light emitting layer EML.

For example, the common electrode CE can be electrically connected to the second common voltage line VSSL. The second common voltage VSS can be applied to the common electrode CE through the second common voltage line VSSL. The pixel electrode PE can be electrically connected directly or indirectly (through another transistor) to the first node N1 of the driving transistor DT of each subpixel SP.

In the disclosure, the “first common voltage VDD” can also be referred to as a “high-potential voltage” or a “driving voltage”, and the “first common voltage line VDDL” can also be referred to as a “high-potential voltage line” or a “driving voltage line”. Further, the “second common voltage VSS” can also be referred to as a “low-potential voltage” or a “base voltage,” and the “second common voltage line VSSL” can also be referred to as a “low-potential voltage line” or a “base voltage line.”

Each light emitting element ED can include portions where the pixel electrode PE, the light emitting layer EML in the intermediate layer LE, and the common electrode CE overlap. A predetermined light emitting area can be formed by each light emitting element ED. For example, the light emitting area of each light emitting element ED can include an overlapping area of the pixel electrode PE, the light emitting layer EML in the intermediate layer EL, and the common electrode CE.

For example, the light emitting element ED can be an organic light emitting diode (OLED), an inorganic light emitting diode (LED), or a quantum dot light emitting element. For example, when the light emitting element ED is an organic light emitting diode (OLED), the intermediate layer EL of the light emitting element ED can include an intermediate layer EL including an organic material.

The driving transistor DT can be a driving transistor for supplying a driving current to the light emitting element ED. The driving transistor DT can be connected between the first common voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. A first common voltage VDD can be applied to the third node N3 from the first common voltage line VDDL.

In the driving transistor DT, the second node N2 can be a gate node, the first node N1 can be a source node or a drain node, and the third node N3 can be a drain node or a source node. Hereinafter, for convenience of description, an example is described in which in the driving transistor DT, the second node N2 can be a gate node (or gate electrode), the first node N1 can be a source node (or source electrode), and the third node N3 can be a drain node (or drain electrode), but embodiments of the disclosure are not limited thereto.

The scan transistor ST included in the subpixel circuit SPC illustrated in FIG. 1 can be a switching transistor for transferring the data signal VDATA, which is an image signal, to the second node N2, which is the gate node of the driving transistor DT.

The scan transistor ST can be controlled to be turned on and off by the scan signal SC, which is a gate signal applied through the scan line SCL, which is a type of the gate line GL, to control electrical connection between the second node N2 of the driving transistor DT and the data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst can be an external capacitor designed to be outside the driving transistor DT, but not a parasite capacitor (e.g., Cgs or Cgd) which is an internal capacitor that can be present between the first node N1 and the second node N2 of the driving transistor DT.

Each of the driving transistor DT and the scan transistor ST can be an n-type transistor or a p-type transistor.

The display panel 110 can have a top emission structure or a bottom emission structure.

When the display panel 110 has a top emission structure, at least a portion of the subpixel circuit SPC can overlap at least a portion of the light emitting element ED in a vertical direction. Accordingly, the area of the emission area can increase and the aperture ratio can increase.

When the display panel 110 has a bottom emission structure, the subpixel circuit SPC may not overlap the light emitting element ED in the vertical direction.

As illustrated in FIG. 1, the subpixel circuit SPC can have a 2T (Transistor) 1C (Capacitor) structure including two transistors DT and ST and one capacitor Cst. In some cases, the subpixel circuit SPC can further include one or more transistors or can further include one or more capacitors.

For example, the subpixel circuit SPC can have an 8T1C structure including 8 transistors and 1 capacitor. As another example, the subpixel circuit SPC can have a 6T2C structure including 6 transistors and 2 capacitors. As another example, the subpixel circuit SPC can have a 7T1C structure including 7 transistors and 1 capacitor. Embodiments of the disclosure are not limited thereto.

Depending on the structure of the subpixel circuit SPC, the type and number of lines of signals supplied to the subpixel SP can vary. Further, the type and the number of common voltages supplied to the subpixel SP can vary depending on the structure of the subpixel circuit SPC.

For example, various types of signal lines can include a plurality of data lines DL transferring data signals (also referred to as data voltages or image signals) and a plurality of gate lines GL transferring gate signals (also referred to as scan signals).

The plurality of data lines DL and the plurality of gate lines GL can cross each other. Each of the plurality of data lines DL can be disposed to extend in the first direction. Each of the plurality of gate lines GL can be disposed to extend in the second direction. The first direction can be a column direction, and the second direction can be a row direction. The first direction can be the row direction, and the second direction can be the column direction. For convenience of description, in the following examples, the first direction is the column direction, and the second direction is the row direction. Thus, described below is an example in which each of the plurality of data lines DL is disposed in the column direction, and each of the plurality of gate lines GL is disposed in the row direction, but embodiments of the disclosure are not limited thereto.

The data driving circuit 120 is a circuit for driving the plurality of data lines DL, and can out data signals to the plurality of data lines DL.

The data driving circuit 120 can receive digital image data DATA from the controller 140 and can convert the received image data DATA into analog data signals and output them to the plurality of data lines DL.

For example, the data driving circuit 120 can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110, but embodiments of the disclosure are not limited thereto.

The data driving circuit 120 can be connected to one side (e.g., an upper or lower side) of the display panel 110. In contrast, depending on the driving scheme or the panel design scheme, data driving circuits 120 can be connected with both the sides (e.g., both the upper and lower sides) of the display panel 110, or two or more of the four sides of the display panel 110.

The data driving circuit 120 can be connected outside the display area DA of the display panel 110, but as another example, the data driving circuit 120 can be disposed in the display area DA of the display panel 110.

The gate driving circuit 130 is a circuit for driving the plurality of gate lines GL, and can output gate signals to the plurality of gate lines GL.

The gate driving circuit 130 can receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the disclosure, the gate driving circuit 130 can be embedded, in a gate in panel (GIP) type, in the display panel 110. When the gate driving circuit 130 is of the gate in panel type, the gate driving circuit 130 can be formed on the substrate 111 of the display panel 110 during the manufacturing process of the display panel 110.

For example, the gate driving circuit 130 can be disposed in the non-display area NDA of the display panel 110.

As another example, the gate driving circuit 130 can be disposed in the display area DA of the display panel 110. In this case, for example, the gate driving circuit 130 can be disposed in a first partial area in the display area DA (e.g., a left area or a right area in the display area DA). As another example, the gate driving circuit 130 can be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type can also be referred to as a “gate-in-panel circuit.”

The controller 140 is a device for controlling the data driving circuit 120 and the gate driving circuit 130 and can control driving timings for the plurality of data lines DL and driving timings for the plurality of gate lines GL.

The controller 140 can supply a data driving control signal DCS to the data driving circuit 120 to control the data driving circuit 120 and can supply a gate driving control signal GCS to the gate driving circuit 130 to control the gate driving circuit 130.

The controller 140 can receive input image data from the host system 150 and supply image data DATA to the data driving circuit 120 based on the input image data.

The controller 140 can be implemented as a separate component from the data driving circuit 120, or the controller 140 and the data driving circuit 120 can be integrated into an integrated circuit (IC).

The controller 140 can be a timing controller used in display technology, a control device that can perform other control functions as well as the functions of the timing controller, or a control device other than the timing controller, or can be a circuit in the control device. The controller 140 can be implemented as various circuits or electronic components, such as an integrated circuit (IC), a field programmable gate array (FPGA), an application specific integrated circuit (ASIC), or a processor, but is not limited thereto.

The controller 140 can be mounted on a printed circuit board or a flexible printed circuit and can be electrically connected with the data driving circuit 120 and the gate driving circuit 130 through the printed circuit board or the flexible printed circuit.

The controller 140 can transmit/receive signals to/from the data driving circuit 120 according to one or more predetermined interfaces. The interface can include, e.g., a low voltage differential signaling (LVDS) interface, an embedded clock point-point interface (EPI) interface, and a serial peripheral interface (SPI), but embodiments of the disclosure are not limited thereto.

To provide a touch sensing function as well as an image display function, the display device 100 according to embodiments of the disclosure can include a touch sensor and a touch sensing circuit that senses the touch sensor to detect whether a touch occurs by a touch object, such as a finger or pen, or the position of the touch.

The touch sensing circuit can include a touch driving circuit that drives and senses the touch sensor and generates and outputs touch sensing data and a touch controller that can detect an occurrence of a touch or the position of the touch using touch sensing data.

The touch sensor can include a plurality of touch electrodes. The touch sensor can further include a plurality of touch lines for electrically connecting the plurality of touch electrodes and the touch driving circuit.

The touch sensor can be present in a touch panel form outside the display panel 110 or can be present inside the display panel 110. When the touch panel, in the form of a touch panel, exists outside the display panel 110, the touch panel is referred to as an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside the display panel 110, the touch sensor can be formed on the substrate, together with signal lines and electrodes related to display driving, during the manufacturing process of the display panel 110.

The touch driving circuit can supply a touch driving signal to at least one of the plurality of touch electrodes and can sense at least one of the plurality of touch electrodes to generate touch sensing data.

The touch sensing circuit can perform touch sensing in a self-capacitance sensing scheme or a mutual-capacitance sensing scheme.

When the touch sensing circuit performs touch sensing in the self-capacitance sensing scheme, the touch sensing circuit can perform touch sensing based on capacitance between each touch electrode and the touch object (e.g., finger or pen). According to the self-capacitance sensing scheme, each of the plurality of touch electrodes can serve both as a driving touch electrode and as a sensing touch electrode. The touch driving circuit can drive all or some of the plurality of touch electrodes and sense all or some of the plurality of touch electrodes.

When the touch sensing circuit performs touch sensing in the mutual-capacitance sensing scheme, the touch sensing circuit can perform touch sensing based on capacitance between the touch electrodes. According to the mutual-capacitance sensing scheme, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or as a single device. The touch driving circuit and the data driving circuit can be implemented as separate devices or as a single device.

The display device 100 can further include a power supply circuit for supplying various types of power to the display driver integrated circuit and/or the touch sensing circuit.

The display device 100 according to embodiments of the disclosure can be a mobile terminal, such as a smart phone or a tablet, or a monitor or television (TV) in various sizes but, without limited thereto, can be a display in various types and various sizes capable of displaying information or images.

The display device 100 according to embodiments of the disclosure can further include an electronic device such as a camera (image sensor), a detection sensor, or the like. For example, the detection sensor can be a sensor that detects an object or a human body by receiving light such as infrared rays, ultrasonic waves, or ultraviolet rays.

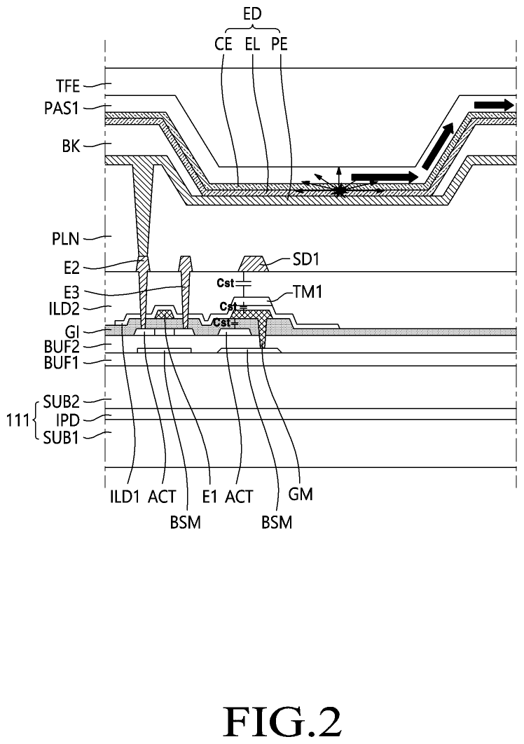

FIG. 2 is an example cross-sectional view illustrating a subpixel SP in a display panel 110 according to embodiments of the disclosure. What is identical or similar to those described with reference to FIG. 1 is omitted from the following description or briefly described below.

Referring to FIG. 2, a transistor TR and a light emitting element ED electrically connected to the transistor TR disposed on the substrate 111 can be disposed in the display area DA.

The transistor TR can include an active layer ACT, a gate electrode E1, a source electrode E2, and a drain electrode E3. The light emitting element ED can include a pixel electrode PE, an intermediate layer EL, and a common electrode CE.

The substrate 111 can include a first substrate SUB1 and a second substrate SUB2, and can include an intermediate film IPD between the first substrate SUB1 and the second substrate SUB2. The first buffer layer BUF1 disposed on the substrate 111 can be a single film or multiple films. A light shield BSM and a second buffer layer BUF2 can be disposed on the first buffer layer BUF1.

An active layer ACT and a first plate ACT can be disposed on the second buffer layer BUF2. A gate insulation layer GI can be disposed on the active layer ACT and the first plate ACT. A gate electrode E1 and a second plate GM can be disposed on the gate insulation layer GI. A first interlayer insulation layer ILD1 can be disposed on the gate electrode E1 and the second plate GM. A third plate TM1 can be disposed on the first interlayer insulation layer ILD1. A second interlayer insulation layer ILD2 can be disposed on the third plate TM1. A source electrode E2, a drain electrode E3, and a fourth plate SD1 can be disposed on the second interlayer insulation layer ILD2. The first to fourth plates ACT, GM, TM1, and SD1 can be disposed to overlap each other, and can constitute a storage capacitor Cst.

A planarization layer PLN can be disposed on the source electrode E2, the drain electrode E3, and the fourth plate SD1. The planarization layer PLN can function to planarize the surface of the substrate 111. The planarization layer PLN can be an insulation layer including an organic insulating material or an inorganic insulating material, but embodiments of the disclosure are not limited thereto.

The planarization layer PLN can include one hole in an area overlapping a portion of the upper surface of the source electrode E2 of the transistor.

The planarization layer PLN can include a concave portion exposing a portion of the upper surface of the planarization layer PLN. The planarization layer PLN can include a peripheral portion extending from the concave portion.

The concave portion can be disposed in the subpixel. The concave portion can include a flat portion, and an inclined portion extending from the flat portion and surrounding the flat portion. The flat portion of the concave portion can correspond to an area where a portion of the upper surface of the planarization layer PLN is exposed. The peripheral portion of the planarization layer PLN can extend from the inclined portion of the concave portion.

A light emitting element ED including a pixel electrode PE, an intermediate layer EL, and a common electrode CE can be disposed on the planarization layer PLN.

The pixel electrode PE can be disposed on the planarization layer PLN. The pixel electrode PE can be disposed on the planarization layer PLN and can be disposed to overlap the concave portion. The pixel electrode PE can include a parallel area where the pixel electrode PE is an area parallel to the surface of the substrate 111 in an area overlapping the flat portion of the concave portion and the peripheral portion of the planarization layer PLN, and an inclined area extending to the inclined portion of the concave portion and having a predetermined angle with respect to the surface of the substrate 111.

The pixel electrode PE of the light emitting element ED can include a reflective material. The pixel electrode PE can include at least one of aluminum, neodymium, nickel, titanium, tantalum, copper (Cu), silver (Ag), and an aluminum alloy, but embodiments of the disclosure are not limited thereto.

In at least one subpixel area, the transistor TR can be electrically connected to the pixel electrode PE of the light emitting element ED through a contact hole penetrating the planarization layer PLN. For example, the source electrode E2 or the drain electrode E3 of the transistor TR can be electrically connected to the pixel electrode PE of the light emitting element ED through a contact hole penetrating the planarization layer PLN.

A bank BK including an opening through which the pixel electrode PE is exposed can be disposed in the concave portion of the planarization layer PLN. The bank BK can be disposed on a portion of the pixel electrode PE and the planarization layer PLN.

An intermediate layer EL can be disposed on the pixel electrode PE and the bank BK exposed by the bank BK. A common electrode CE can be disposed on the intermediate layer EL.

The common electrode CE can be disposed on the intermediate layer EL.

The common electrode CE can include a conductive material through which light is transmitted or semi-transmitted. For example, the common electrode CE can include at least one type of transparent conductive oxide such as indium tin oxide (ITO), indium zinc oxide (IZO), indium tin zinc oxide (ITZO), zinc oxide, tin oxide, or a transflective metal such as magnesium (Mg), silver (Ag), or an alloy of magnesium and silver. Here, when the common electrode CE includes a transflective metal, the thickness of the common electrode CE can be smaller than that of the pixel electrode PE.

In the display panel 110 according to embodiments of the disclosure, the emission area EA disposed in the display area DA can include a main emission area and an auxiliary emission area. The main emission area can be an area corresponding to an area where the pixel electrode PE, the intermediate layer EL, and the common electrode CE are sequentially stacked to overlap each other. The main emission area can be an area where light emitted from the intermediate layer EL is extracted from the opening area to the outside. The auxiliary emission area can be an area through which light reflected from the inclined surface is emitted. The auxiliary emission area can be an area where light emitted from the intermediate layer EL is reflected from the pixel electrode PE disposed on the inclined surface of the planarization layer PLN and extracted to the outside.

An encapsulation layer can be positioned on the common electrode CE of the light emitting element ED.

The encapsulation layer can be a layer that prevents moisture or oxygen from penetrating into the light emitting elements ED disposed under the encapsulation layer. The encapsulation layer can prevent moisture or oxygen from penetrating into the intermediate layer EL. Here, the encapsulation layer can be composed of a single film or multiple films.

The encapsulation layer can include a first encapsulation layer PAS1, a second encapsulation layer TFT, and a third encapsulation layer. The first encapsulation layer PAS1 and the third encapsulation layer can be an inorganic layer including an inorganic insulating material, and the second encapsulation layer TFE can be an organic layer including an organic insulating material.

As the second encapsulation layer TFE is formed of an organic film, the second encapsulation layer TFE can serve as a planarization layer.

Meanwhile, a portion of the light emitted from the main emission area travels laterally along the first encapsulation layer PAS1 in the first encapsulation layer PAS1, which is a transparent inorganic layer, by a light guide effect. In this case, the light traveling laterally may not be reflected by the pixel electrode PE disposed on the inclined portion of the concave portion but can be lost, or can proceed to an adjacent subpixel, causing color mixing. Accordingly, there is a need for a structure that blocks the light guide effect of light by the encapsulation layer.

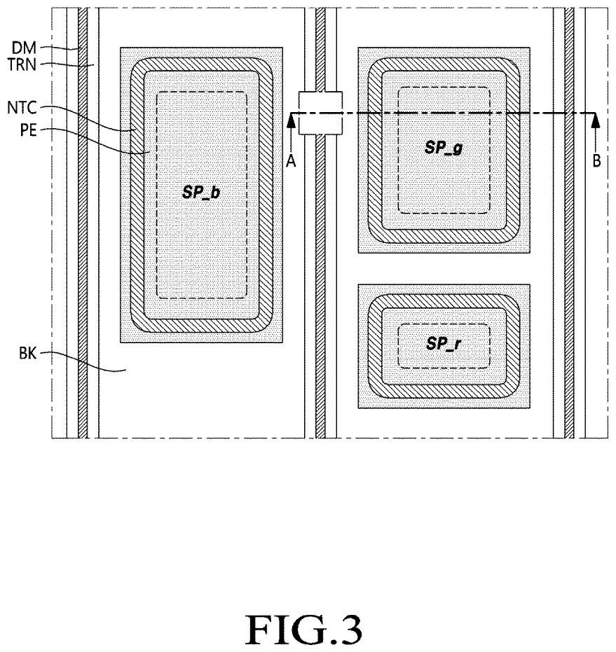

FIG. 3 is an example plan view illustrating a layout of a subpixel SP according to embodiments of the disclosure. What is identical or similar to those described in connection with FIGS. 1 and 2 can be omitted or briefly described below.

Referring to FIG. 3, the display panel 110 according to embodiments of the disclosure can include a plurality of subpixels SP. The plurality of subpixels SP can include a first subpixel SP_r emitting red light, a second subpixel SP_g emitting green light, and a third subpixel SP_b emitting blue light.

Each subpixel SP can be surrounded by a bank BK. For example, the bank BK can define an area of each subpixel SP.

The bank BK can include a trench TRN and a convex pattern DM in a first direction (e.g., a column direction). The convex pattern DM can be disposed between a pair of trenches TRN. The convex pattern DM can be formed to protrude in a vertical direction from the substrate. The convex pattern DM can include the same material as the bank DM material. By providing the trench TRN and the convex pattern DM on the bank BK, it is possible to block the movement of the side leakage current to the adjacent subpixel SP.

Further, the bank BK can include at least one spacer SPE disposed between a plurality of subpixels SP. The spacer SPE can be formed to protrude in a vertical direction from the substrate. The spacer SPE can include the same material as the bank DM material. The height of the spacer SPE can be more than the height of the convex pattern DM.

A notch pattern NTC can be disposed to overlap an outer portion of the pixel electrode PE. The notch pattern NTC can be disposed to extend along the outer portion of the pixel electrode PE, but the disclosure is not limited thereto.

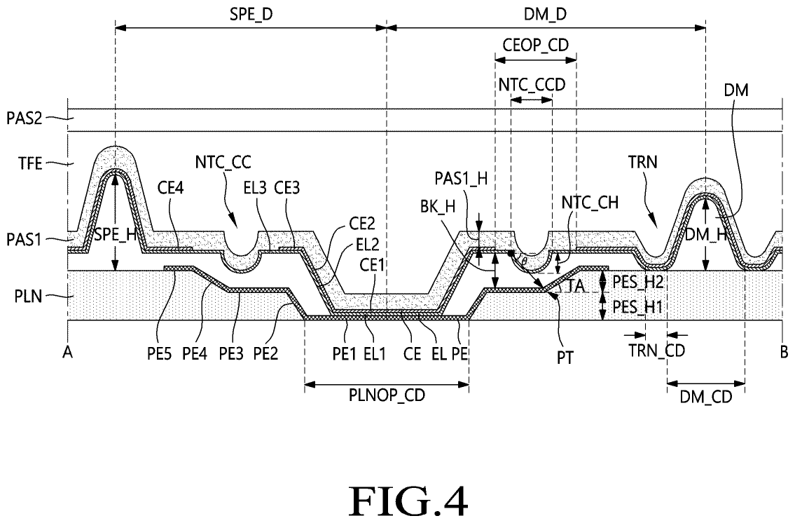

FIGS. 4 to 6 are example cross-sectional views illustrating a display panel 110 taken along line A-B of FIG. 3, according to embodiments of the disclosure. What is identical or similar to those described with reference to FIGS. 1 to 3 is omitted from the following description or briefly described below.

The cross-sectional shape of the display panel 110 according to embodiments of the disclosure illustrated in FIGS. 4 to 6 illustrates some components disposed on the planarization layer PLN in the cross-sectional shape of the display panel 110 according to embodiments of the disclosure illustrated in FIG. 2.

Referring to FIGS. 4 to 6, the planarization layer PLN can include an opening area PLNOP. The planarization layer PLN can include a concave portion and a peripheral portion surrounding the concave portion. The concave portion can include a flat portion and an inclined portion surrounding the flat portion. The inclined portion can include a first inclined portion and a second inclined portion. A vertical height PES_H1 of the first inclined portion can be larger than a vertical height PES_H2 of the second inclined portion. The inclined portion can be positioned between the first inclined portion and the second inclined portion, and can include a sub flat portion connecting the first inclined portion and the second inclined portion. The inclination angle of the first inclined portion can be larger than the inclination angle of the second inclined portion.

The pixel electrode PE can be disposed on the planarization layer PLN. The pixel electrode PE can include a first portion PE1, a second portion PE2, a third portion PE3, a fourth portion PE4, and a fifth portion PE5. The first portion PE1 of the pixel electrode PE can correspond to the flat portion of the concave portion. The second to fourth portions PE2, PE3, and PE4 of the pixel electrode PE can correspond to the inclined portion of the concave portion. The second portion PE2 of the pixel electrode PE can correspond to the first inclined portion of the concave portion. The third portion PE3 of the pixel electrode PE can correspond to the sub flat portion of the concave portion. The fourth portion PE4 of the pixel electrode PE can correspond to the second inclined portion of the concave portion. The fifth portion PE5 of the pixel electrode PE can correspond to the peripheral portion of the planarization layer PLN.

A bank BK can be disposed on the pixel electrode PE and the planarization layer PLN. The bank BK can be disposed to expose the pixel electrode PE in the opening area PLNOP of the planarization layer PLN. The bank BK can have an opening area overlapping at least a portion of the concave portion. The bank BK can be disposed outside the flat portion of the concave portion, the inclined portion of the concave portion, and the peripheral portion of the planarization layer. The thickness BK_H of the bank BK in the sub flat portion can be larger than the vertical height PES_H2 of the second inclined portion. The bank BK can include a low refractive organic insulating material. For example, the bank BK can include an organic insulating material having a refractive index n of about 1.6.

An intermediate layer EL can be disposed on the pixel electrode PE and the bank BK. The intermediate layer EL can include a first portion EL1, a second portion EL2, and a third portion EL3. The first portion EL1 of the intermediate layer EL can correspond to the first portion PE1 of the pixel electrode PE disposed in the opening area of the bank BK. The second portion EL2 of the intermediate layer EL can correspond to an inclined surface of the opening area of the bank BK. The third portion EL3 of the intermediate layer EL can correspond to the upper surface of the bank Bk.

A common electrode CE can be disposed on the intermediate layer EL. The common electrode CE can include a first portion CE1, a second portion CE2, a third portion CE3, and a fourth portion CE. The first portion CE1 of the common electrode CE can correspond to the first portion PE1 of the pixel electrode PE disposed in the opening area of the bank BK. The second portion CE2 of the common electrode CE can correspond to the inclined surface of the opening area of the bank BK. The third portion CE3 of the common electrode CE can correspond to a portion of the upper surface of the bank BK. The fourth portion CE4 of the common electrode CE can correspond to the upper surface of the bank BK spaced apart from the third portion CE3 of the common electrode CE. The common electrode CE can have a common electrode opening area CEOP between the third portion CE3 and the fourth portion CE4.

It can include a notch pattern NTC positioned in an area corresponding to an outer portion of the concave portion and disposed in the bank BK.

The notch pattern NTC can be disposed at a position overlapping the inclined portion of the concave portion. For example, the notch pattern NTC can be disposed to at least partially overlap the second inclined portion of the concave portion. For example, the notch pattern NTC can be disposed to at least partially overlap the point PT where the sub flat portion of the concave portion and the second inclined portion of the concave portion contact each other.

The notch pattern NTC can be disposed to at least partially overlap the third and fourth portions PE3 and PE4 of the pixel electrode PE. For example, the notch pattern NTC can be disposed to at least partially overlap the point PT where the third portion PE3 and the fourth portion PE4 of the pixel electrode PE contact each other.

The notch pattern NTC can have a semi-circular cross section.

An angle between a tangent line to the notch pattern NTC and an upper surface of the bank BK can be more than 0 and less than 90°. The angle between a tangent line to the notch pattern NTC and the upper surface of the bank BK can increase in the above-described range. The slope of the tangent line to the notch pattern NTC can be discontinuous.

The notch pattern NTC can be disposed not to overlap at least a portion of the common electrode CE. For example, the width of the notch pattern NTC can be smaller than the width of the open area CEOP_CD of the common electrode CE.

Meanwhile, the inclination angle of the second inclined portion can be derived using the maximum dispersion angle of light traveling through the first encapsulation layer PAS1. For example, the inclination angle of the second inclined portion can be equal to (90°−maximum dispersion angle of light)/2.

Referring to FIGS. 4 to 6, a first encapsulation layer PAS1 can be disposed on the common electrode CE. The first encapsulation layer PAS1 can be a transparent insulation layer including an inorganic insulating material. The first encapsulation layer PAS1 can include a high refractive inorganic insulating material. For example, the first encapsulation layer PAS1 can include an inorganic insulating material having a refractive index n of about 1.9.

The second encapsulation layer TFE can be disposed on the first encapsulation layer PAS1. The second encapsulation layer TFE can be a transparent insulation layer including an organic insulating material. The second encapsulation layer TFE can include an organic insulating material with a low refractive index. For example, the second encapsulation layer TFE can include an organic insulating material having a refractive index n of about 1.5.

A third encapsulation layer PAS2 can be disposed on the second encapsulation layer TFE. The third encapsulation layer PAS2 can be a transparent insulation layer including an inorganic insulating material. The third encapsulation layer PAS2 can include a high refractive inorganic insulating material. For example, the third encapsulation layer PAS2 can include an inorganic insulating material having a refractive index n of about 1.9.

A portion of the light emitted from the light emitting element ED can travel laterally in the first encapsulation layer PAS1 which is a transparent inorganic layer by the light guide effect and be lost or proceed to an adjacent subpixel, causing color mixing. In other words, the first encapsulation layer PAS1 is disposed between the bank BK having a low refractive index and the second encapsulation layer TFE, so that light entering the first encapsulation layer PAS1 is totally reflected and may not be extracted to the outside (e.g., in a direction perpendicular to the substrate).

Accordingly, by providing the notch pattern NTC at the point overlapping the inclined portion of the concave portion in the display panel 110 according to embodiments of the disclosure, the light trapped in the first encapsulation layer PAS1 can proceed to the second inclined portion, which is the fourth portion PE4 of the pixel electrode PE, and then be reflected from the fourth portion PE4 of the pixel electrode PE to be extracted to the outside.

A trench TRN and a convex pattern DM can be disposed between the subpixels SP. The convex pattern DM can be disposed between a pair of trenches TRN. Further, a spacer SPE can be disposed between the subpixels SP. The spacer SPE can be disposed in a partial area. The height SPE_H of the spacer SPE can be larger than the height DM_H of the convex pattern DM.

The distance SPE_D from the center of the subpixel SP to the spacer SPE and the distance DM_D from the center of the subpixel SP to the convex pattern DM can be the same, but the disclosure is not limited thereto. The distance DM_D from the center of the subpixel SP to the convex pattern DM can be defined as the sum of the width PLNOP_CD/2 of the opening area of the planarization layer PLN, the gap BK_CD of the banks BK, the gap TRN_CD of the trench TRN, and the width DM_CD of the convex pattern DM/2.

Referring to FIG. 4, the notch pattern NTC can have a concave notch pattern NTC_CC including a pattern having a shape concave inward from the upper surface of the bank BK.

In this case, the width NTC_CCD of the concave notch pattern NTC_CC can be smaller than the width CEOP_CD of the opening area of the common electrode CE. Further, the height NTC_CH of the concave notch pattern NTC_CC can be smaller than the height BK_H of the bank BK in the sub flat portion. Further, a difference between the height BK_H of the bank BK and the height NTC_CH of the concave notch pattern NTC_CC can be smaller than the height PES_H2 of the second inclined portion.

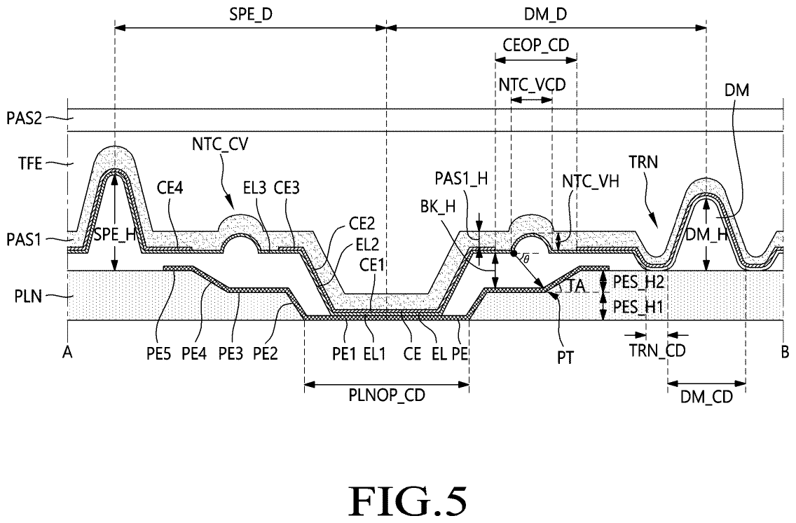

Referring to FIG. 5, the notch pattern NTC can have a convex notch pattern NTC_CV including a pattern protruding from the upper surface of the bank BK.

In this case, the width NTC_VCD of the convex notch pattern NTC_CV can be smaller than the width CEOP_CD of the opening area of the common electrode CE. Further, the height NTC_VH of the convex notch pattern NTC-CV can be smaller than the height DM_H of the convex pattern DM.

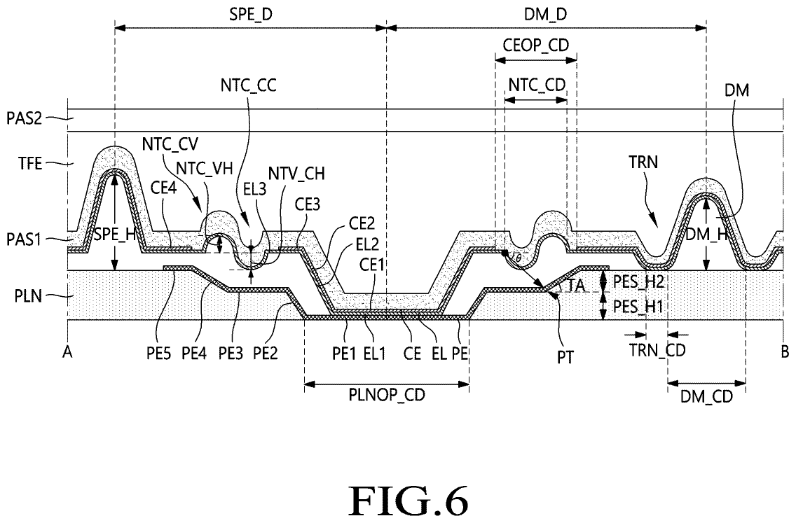

Referring to FIG. 6, the notch pattern NTC can have a concave notch pattern NTC_CC and a convex notch pattern NTC_CV.

In this case, the sum of the width NTC_CCD of the concave notch pattern NTC_CC and the width NTC_VCD of the convex notch pattern NTC_CV can be smaller than the width CEOP_CD of the opening area of the common electrode CE. Further, the height NTC_CH of the concave notch pattern NTC_CC can be smaller than the height BK_H of the bank BK in the sub flat portion. Further, the height NTC_VH of the convex notch pattern NTC-CV can be smaller than the height DM_H of the convex pattern DM. Further, a difference between the height BK_H of the bank BK and the height NTC_CH of the concave notch pattern NTC_CC can be smaller than the height PES_H2 of the second inclined portion.

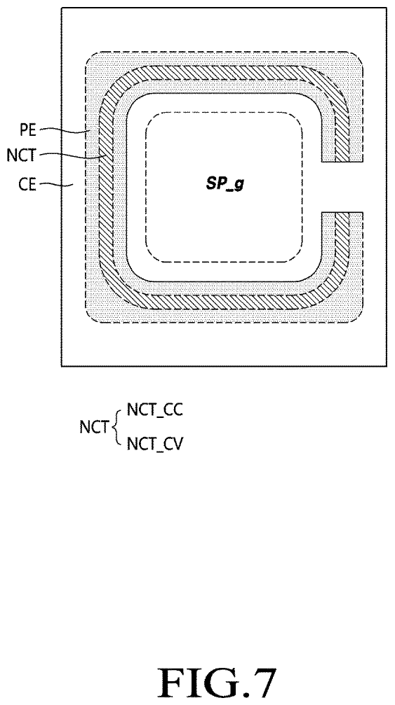

FIGS. 7 to 11 are example plan views illustrating a subpixel SP according to embodiments of the disclosure. What is identical or similar to those described with reference to FIGS. 1 to 6 is omitted from the following description or briefly described below.

Referring to FIG. 7, the notch pattern NTC can be disposed around the inside of the subpixel SP_g. The notch pattern NTC may not be disposed in the area where the common electrode CE is disposed. The common electrode CE can be disposed to overlap the pixel electrode PE. The common electrode CE can be patterned and disposed along the notch pattern NTC. The notch pattern NTC and the pixel electrode PE can be exposed in the area where the common electrode CE is patterned. In this case, the notch pattern NTC can be a concave notch pattern NTC_CC or a convex notch pattern NTC_CV.

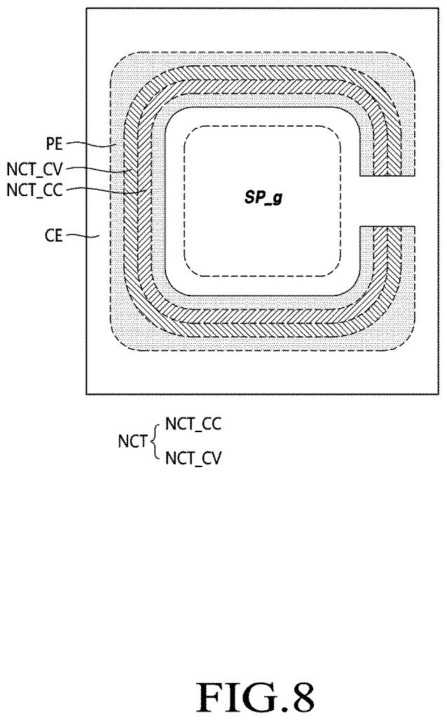

Referring to FIG. 8, the notch pattern NTC can include a concave notch pattern NTC_CC and a convex notch pattern NTC_CV. The convex notch pattern NTC_CV can be disposed to surround the concave notch pattern NTC_CC. The notch patterns NTC_CC and NTC_CV may not be disposed in an area where the common electrode CE is disposed. The common electrode CE can be disposed to overlap the pixel electrode PE. The common electrode CE can be patterned and disposed along the notch patterns NTC_CC and NTC_CV. The notch patterns NTC_CC and NTC_CV and the pixel electrode PE can be exposed in the area where the common electrode CE is patterned.

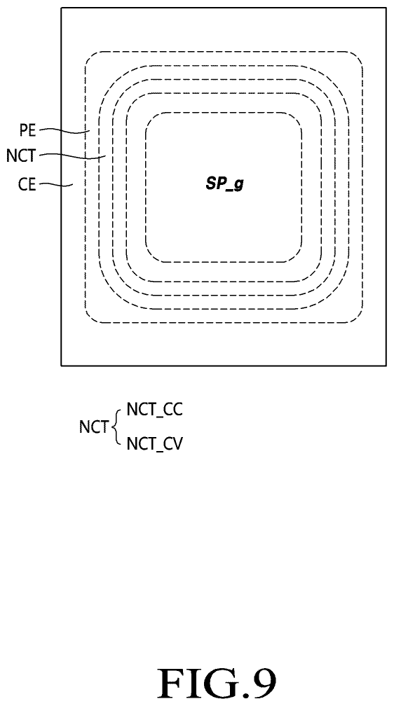

Referring to FIG. 9, the common electrode CE can be disposed to cover the pixel electrode PE and the notch pattern NTC. In this case, the notch pattern NTC can be disposed in a continuous state without being broken.

Referring to FIGS. 7 to 9, when the notch pattern NTC is disposed in a continuous state, light traveling through the first encapsulation layer PAS1 can be dispersed from the notch pattern NTC forward from the display panel 110 or can proceed to the fourth portion PE4 of the pixel electrode PE disposed on the second inclined portion of the concave portion to be reflected to the outside.

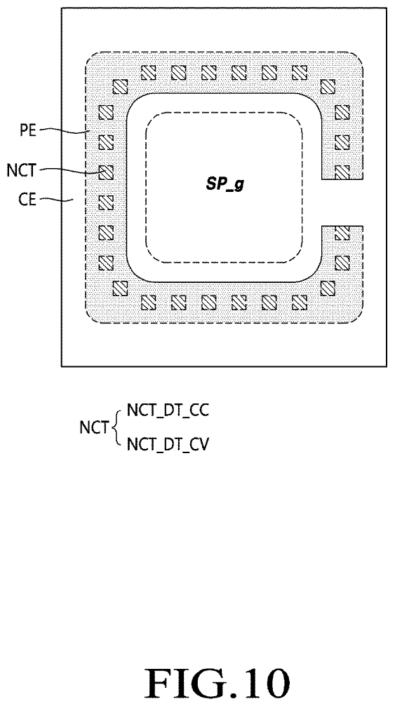

Referring to FIG. 10, the notch pattern NTC can have a dot shape. For example, the notch pattern NTC can have dot shapes disposed around the inside of the subpixel SP_g at regular intervals. The notch pattern NTC may not be disposed in the area where the common electrode CE is disposed. The common electrode CE can be disposed to overlap the pixel electrode PE. The common electrode CE can be patterned and disposed along the notch pattern NTC. The notch pattern NTC and the pixel electrode PE can be exposed in the area where the common electrode CE is patterned. In this case, the notch pattern NTC can be a concave dot notch pattern NTC_DT_CC or a convex dot notch pattern NTC_DT_CV.

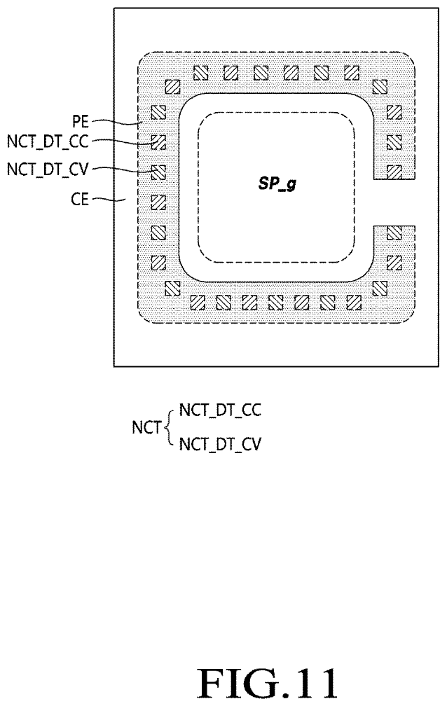

Referring to FIG. 11, in the notch pattern NTC, the concave dot notch pattern NTC_DT_CC and the convex dot notch pattern NTC_DT_CV can be alternately disposed at regular intervals along the inner periphery of the subpixel SP_g. The notch pattern NTC may not be disposed in the area where the common electrode CE is disposed. The common electrode CE can be disposed to overlap the pixel electrode PE. The common electrode CE can be patterned and disposed along the notch pattern NTC. The notch pattern NTC and the pixel electrode PE can be exposed in the area where the common electrode CE is patterned.

Referring to FIGS. 10 and 11, when the notch pattern NTC is disposed in a dot shape, light traveling through the first encapsulation layer PAS1 can distribute an optical path from the dot-shaped notch pattern NTC to the center of the dot.

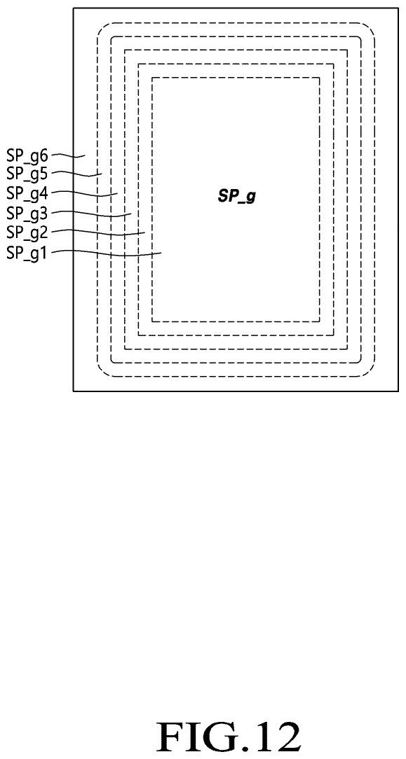

FIG. 12 is an example plan view illustrating an emission area EA of a subpixel SP according to embodiments of the disclosure. What is identical or similar to those described with reference to FIGS. 1 to 11 is omitted from the following description or briefly described below.

Referring to FIG. 12, the subpixel SP_g can include an emission area. The emission area can include a first area SP_g1 positioned in a center portion of the emission area, a second area SP_g2 surrounding the first area SP_g1, a third area SP_g3 surrounding the second area SP_g2, a fourth area SP_g4 surrounding the third area SP_g3, and a fifth area SP_g5 surrounding the fourth area SP_g4. The first area SP_g1, the second area SP_g2, the third area SP_g3, the fourth area SP_g4, and the fifth area SP_g5 can be connected without being spaced apart from each other.

The second area SP_g2 can have a lower luminance than those of the first area SP_g1 and the third area SP_g3. The fourth area SP_g4 can have a lower luminance than those of the third area SP_g3 and the fifth area SP_g5.

For example, the first area SP_g1 can be an area corresponding to the flat portion of the concave portion. The third area SP_g3 can be an area corresponding to the first inclined portion of the concave portion. The fifth area SP_g5 can be an area corresponding to the second inclined portion of the concave portion.

The sixth area SP_g6 is an area surrounding the emission area, and can be a non-emission area that is an area between the emission areas.

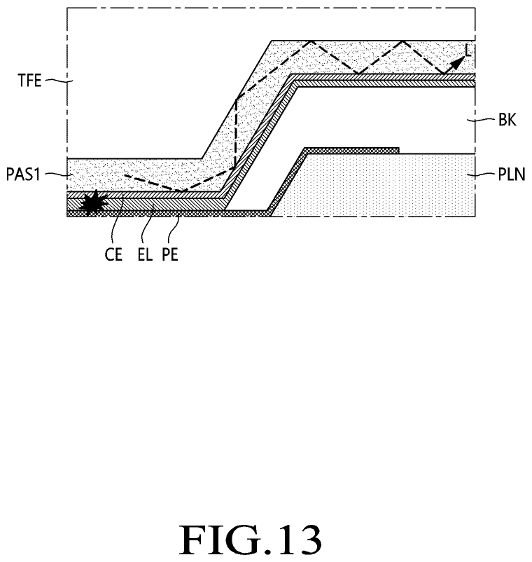

FIGS. 13 to 16 are example plan views illustrating a principle of light extraction by a display device 100 according to embodiments of the disclosure. Those identical or similar to what has been described with reference to FIGS. 1 to 12 are omitted from the following description or are briefly described.

Referring to FIG. 13, a portion of the light emitted from the emission area travels laterally along the first encapsulation layer PAS1 in the first encapsulation layer PAS1, which has a high refractive index, by the light guide effect. In this case, the light L traveling laterally may not be reflected by the pixel electrode PE disposed on the inclined portion of the concave portion but can be lost, or can proceed to an adjacent subpixel, causing color mixing.

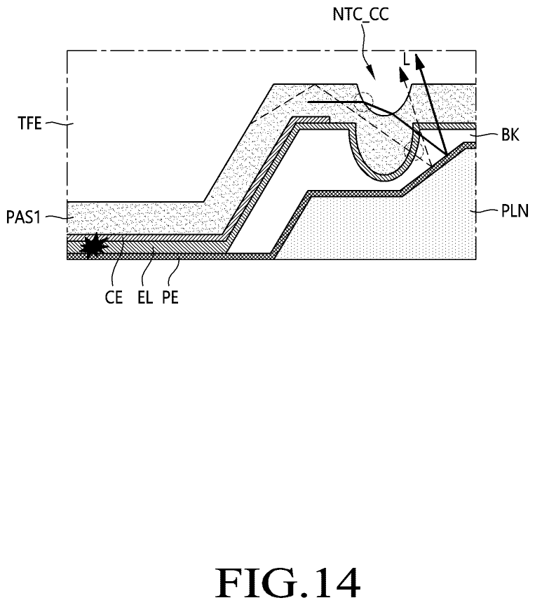

Referring to FIG. 14, a portion of the light emitted from the emission area travels laterally along the first encapsulation layer PAS1 in the first encapsulation layer PAS1, which has a high refractive index, by the light guide effect. In this case, light L can be extracted to the outside by being dispersed from the concave notch pattern NTC_CC along the concave lens optical path and reflected from the pixel electrode PE disposed on the second inclined surface of the concave portion.

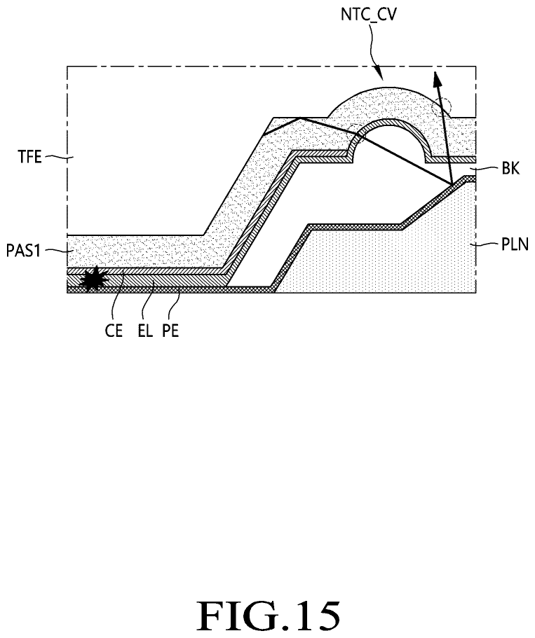

Referring to FIG. 15, a portion of the light emitted from the emission area travels laterally along the first encapsulation layer PAS1 in the first encapsulation layer PAS1, which has a high refractive index, by the light guide effect. In this case, light L can be extracted to the outside by being reflected from the pixel electrode PE disposed on the second inclined surface of the concave portion by the focusing effect of the convex lens in the convex notch pattern NTC_CV.

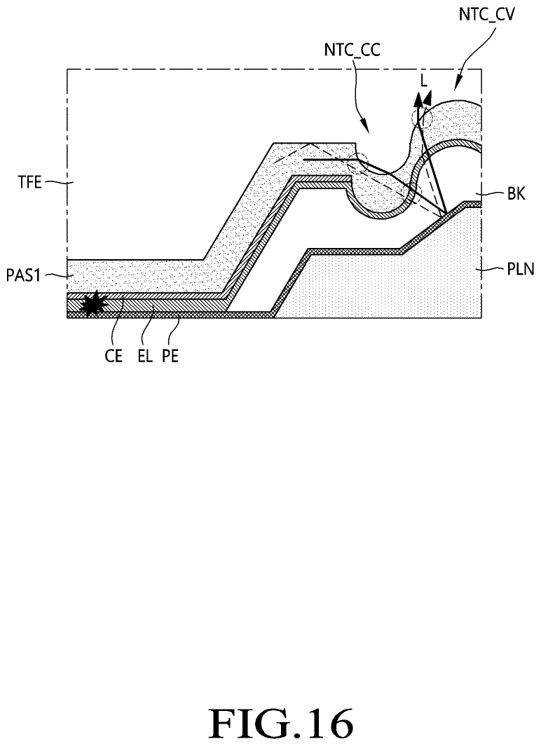

Referring to FIG. 16, a portion of the light emitted from the emission area travels laterally along the first encapsulation layer PAS1 in the first encapsulation layer PAS1, which has a high refractive index, by the light guide effect. In this case, light L can be extracted to the outside by being reflected from the pixel electrode PE disposed on the second inclined surface of the concave portion by the focusing effect of the convex lens in the concave notch pattern NTC_CC.

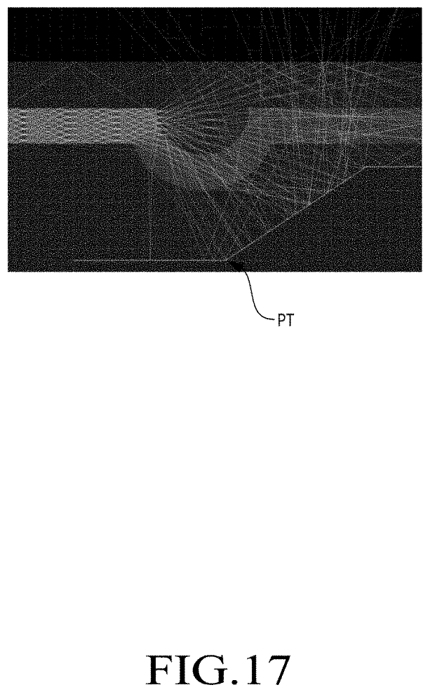

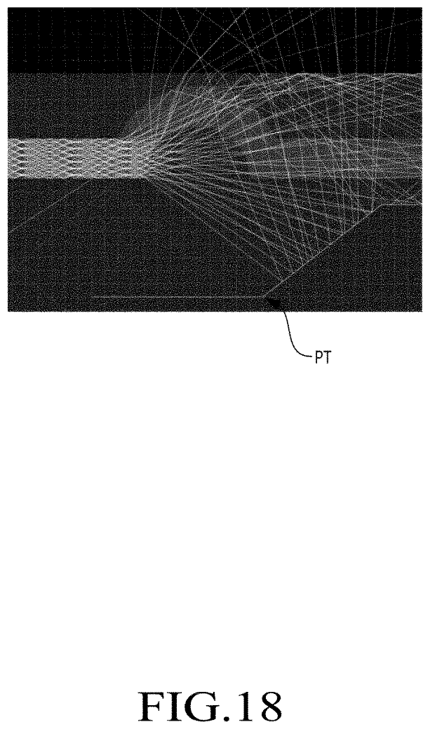

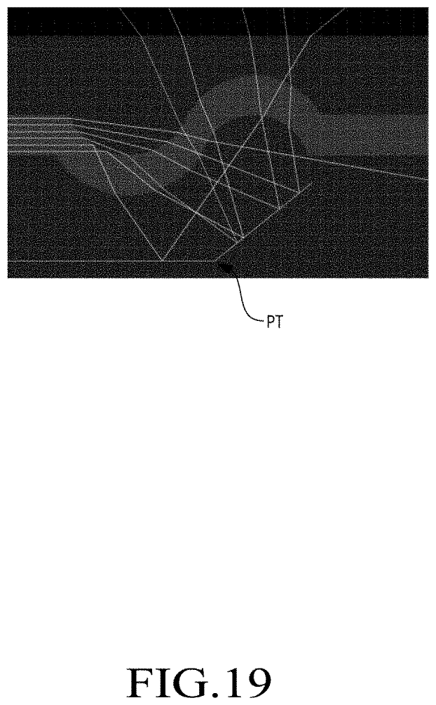

FIGS. 17 to 19 illustrate examples of simulation results showing a light extraction path for a display device 100 according to embodiments of the disclosure. What is identical or similar to those described with reference to FIGS. 1 to 16 is omitted from the following description or briefly described below.

Referring to FIGS. 17 to 19, it can be identified that the direction of the light guided in the first encapsulation layer is redirected from the concave notch pattern NTC_CC and/or the convex notch pattern NTC_CV to the second inclined surface of the concave portion and is extracted to the outside by the pixel electrode disposed on the second inclined surface of the concave part.

A display device according to various embodiments of the disclosure can be described as follows.

According to embodiments of the disclosure, there can be provided a display device comprising a substrate having a plurality of subpixels, an insulation layer including a concave portion disposed in the plurality of subpixels and a peripheral portion surrounding the concave portion, a pixel electrode positioned in the concave portion and the peripheral portion, a bank positioned on the pixel electrode and the insulation layer and having an opening area overlapping at least a portion of the concave portion, an intermediate layer positioned on the opening area of the bank and the bank, a common electrode positioned on the intermediate layer, an encapsulation layer positioned on the common electrode, and a notch pattern positioned in an area corresponding to an outer portion of the concave portion and disposed in the bank.

By the display device according to embodiments of the disclosure, the concave portion can include a flat portion and an inclined portion surrounding the flat portion. The notch pattern can be disposed at a position overlapping the inclined portion.

By the display device according to embodiments of the disclosure, the inclined portion can include a first inclined portion and a second inclined portion. The notch pattern can be disposed to at least partially overlap the second inclined portion.

By the display device according to embodiments of the disclosure, the inclined portion can further include a sub flat portion positioned between the first inclined portion and the second inclined portion. The notch pattern can be disposed to at least partially overlap a point where the sub flat portion and the second inclined portion contact each other.

By the display device according to embodiments of the disclosure, an inclination angle of the first inclined portion can be larger than an inclination angle of the second inclined portion.

By the display device according to embodiments of the disclosure, each of the plurality of subpixels can include an emission area. The emission area can include a first area positioned in a central portion of the emission area, a second area surrounding the first area, and a third area surrounding the second area. The second area can have a lower luminance than the first area and the third area.

The display device according to embodiments of the disclosure can comprise a fourth area surrounding the third area and a fifth area surrounding the fourth area. The fourth area can have a lower luminance than the third area and the fifth area.

By the display device according to embodiments of the disclosure, the first area, the second area, the third area, the fourth area, and the fifth area may not be spaced apart but connected to each other.

By the display device according to embodiments of the disclosure, the first area can be an area corresponding to the flat portion of the concave portion.

By the display device according to embodiments of the disclosure, the third area can be an area corresponding to the first inclined portion of the concave portion.

By the display device according to embodiments of the disclosure, the fifth area can be an area corresponding to the second inclined portion of the concave portion.

By the display device according to embodiments of the disclosure, the notch pattern can have a semi-circular cross section. An angle between an upper surface of the bank and a tangent line to the notch pattern can be more than 0° and less than 90°.

By the display device according to embodiments of the disclosure, the notch pattern can include a pattern having a shape concave inward from the upper surface of the bank.

By the display device according to embodiments of the disclosure, the notch pattern can include a pattern having a shape protruding from the upper surface of the bank.

By the display device according to embodiments of the disclosure, the notch pattern can further include a pattern protruding from the upper surface of the bank.

By the display device according to embodiments of the disclosure, at least a portion of the common electrode can be disposed not to overlap the notch pattern.

By the display device according to embodiments of the disclosure, the notch pattern can be disposed to extend along the opening area of the bank.

By the display device according to embodiments of the disclosure, the notch pattern can be disposed along the opening area of the bank and can have a plurality of dot patterns disposed at equal intervals.

By the display device according to embodiments of the disclosure, the bank can include at least one trench disposed between the plurality of subpixels.

By the display device according to embodiments of the disclosure, the bank can include at least one convex pattern disposed between the plurality of subpixels and adjacent to the trench.

By the display device according to embodiments of the disclosure, the bank can include at least one spacer disposed between the plurality of subpixels. A height of the spacer can be larger than a height of the convex pattern.

By the display device according to embodiments of the disclosure, the encapsulation layer can include a first encapsulation layer, a second encapsulation layer on the first encapsulation layer, and a third encapsulation layer on the second encapsulation layer. A refractive index of the first encapsulation layer can be higher than a refractive index of the bank and the second encapsulation layer.

According to embodiments of the disclosure, there can be provided a display device comprising a substrate including a display area including an emission area and a non-display area surrounding the display area, an insulation layer positioned in the display area and including a concave portion and a peripheral portion surrounding the concave portion, a pixel electrode disposed on the insulation layer, a bank having an opening area overlapping at least a portion of the concave portion, an intermediate layer disposed on the pixel electrode and the bank, a common electrode positioned on the intermediate layer, an encapsulation layer positioned on the common electrode, and a notch pattern spaced apart from the opening area of the bank and disposed on the bank along the opening area of the bank.

By the display device according to embodiments of the disclosure, the concave portion can include a flat portion and an inclined portion disposed between the flat portion and the peripheral portion. The inclined portion can include a first inclined portion and a second inclined portion. The notch pattern can be disposed to at least partially overlap the second inclined portion.

By the display device according to embodiments of the disclosure, the inclined portion can further include a sub flat portion positioned between the first inclined portion and the second inclined portion. The notch pattern can be disposed to at least partially overlap a point where the sub flat portion and the second inclined portion contact each other.

By the display device according to embodiments of the disclosure, in a cross-sectional shape of the notch pattern, a start point of the notch pattern can be positioned closer to the flat portion of the concave portion than a point where the sub flat portion and the second inclined portion contact each other.

According to embodiments of the disclosure, there can be provided a display device capable of enhancing light extraction efficiency.

According to embodiments of the disclosure, there can be provided a display device capable of extracting an optical waveguide component by an encapsulation layer by incorporating a light extraction pattern in a non-emission area.

According to embodiments of the disclosure, there can be provided a display device capable of enhancing light extraction efficiency by blocking the light propagating to the adjacent subpixel by incorporating a light extraction pattern in a non-emission area.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the disclosure. The above description and the accompanying drawings provide an example of the technical idea of the disclosure for illustrative purposes only. For example, the disclosed embodiments are intended to illustrate the scope of the technical idea of the disclosure.

What is claimed:

1. A display device, comprising:
a substrate having a plurality of subpixels;
an insulation layer including a concave portion disposed in the plurality of subpixels and a peripheral portion adjacent to the concave portion;
a pixel electrode disposed in the concave portion and the peripheral portion;
a bank disposed on the pixel electrode and the insulation layer, and having an opening area overlapping at least a portion of the concave portion;
an intermediate layer disposed on the opening area of the bank;
a common electrode disposed on the intermediate layer;
an encapsulation layer disposed on the common electrode; and
a notch pattern disposed in an area corresponding to an outer portion of the concave portion and disposed in the bank.

2. The display device of claim 1, wherein the concave portion of the insulation layer includes a flat portion and an inclined portion surrounding the flat portion, and
wherein the notch pattern is disposed at a position overlapping the inclined portion of the concave portion.

3. The display device of claim 2, wherein the inclined portion of the insulation layer includes a first inclined portion and a second inclined portion, and
wherein the notch pattern is disposed to at least partially overlap the second inclined portion of the inclined portion.

4. The display device of claim 3, wherein the inclined portion of the insulation layer further includes a sub flat portion disposed between the first inclined portion and the second inclined portion, and
wherein the notch pattern is disposed to at least partially overlap a point where the sub flat portion and the second inclined portion contact each other.

5. The display device of claim 3, wherein an inclination angle of the first inclined portion is larger than an inclination angle of the second inclined portion.

6. The display device of claim 4, wherein each of the plurality of subpixels includes an emission area,
wherein the emission area includes:
a first area disposed in a central portion of the emission area,
a second area surrounding the first area, and
a third area surrounding the second area, and
wherein the second area has a lower luminance than the first area and the third area.

7. The display device of claim 6, wherein the emission area further includes a fourth area surrounding the third area and a fifth area surrounding the fourth area, and
wherein the fourth area has a lower luminance than the third area and the fifth area.

8. The display device of claim 7, wherein the first area, the second area, the third area, the fourth area, and the fifth area of the emission area are not spaced apart but are connected to each other.

9. The display device of claim 7, wherein the first area of the emission area is an area corresponding to the flat portion of the concave portion, or
wherein the third area of the emission area is an area corresponding to the first inclined portion of the concave portion, or wherein the fifth area of the emission area is an area corresponding to the second inclined portion of the concave portion.

10. The display device of claim 1, wherein the notch pattern has a semi-circular cross section, and
wherein an angle between an upper surface of the bank and a tangent line to the notch pattern is more than 0° and less than 90°.

11. The display device of claim 1, wherein the notch pattern includes a pattern having a shape concave inward from an upper surface of the bank, or
wherein the notch pattern includes a pattern having a shape protruding from the upper surface of the bank, or
wherein the notch pattern further includes a pattern protruding from the upper surface of the bank.

12. The display device of claim 1, wherein at least a portion of the common electrode is disposed not to overlap the notch pattern.

13. The display device of claim 1, wherein the notch pattern is disposed to extend along the opening area of the bank.

14. The display device of claim 1, wherein the notch pattern is disposed along the opening area of the bank and has a plurality of dot patterns disposed at equal intervals.

15. The display device of claim 1, wherein the bank includes at least one trench disposed between the plurality of subpixels.

16. The display device of claim 15, wherein the bank includes at least one convex pattern disposed between the plurality of subpixels and adjacent to the at least one trench.

17. The display device of claim 16, wherein the bank includes at least one spacer disposed between the plurality of subpixels, and
wherein a height of the at least one spacer is larger than a height of the at least one convex pattern.

18. The display device of claim 1, wherein the encapsulation layer includes a first encapsulation layer, a second encapsulation layer on the first encapsulation layer, and a third encapsulation layer on the second encapsulation layer, and
wherein a refractive index of the first encapsulation layer is higher than a refractive index of the bank and the second encapsulation layer.

19. A display device, comprising:
a substrate including a display area including an emission area and a non-display area adjacent to the display area;
an insulation layer disposed in the display area, and including a concave portion and a peripheral portion adjacent to the concave portion;
a pixel electrode disposed on the insulation layer;
a bank having an opening area overlapping at least a portion of the concave portion;
an intermediate layer disposed on the pixel electrode and the bank;
a common electrode disposed on the intermediate layer;
an encapsulation layer disposed on the common electrode; and
a notch pattern spaced apart from the opening area of the bank and disposed on the bank along the opening area of the bank.

20. The display device of claim 19, wherein the concave portion of the insulation layer includes a flat portion and an inclined portion disposed between the flat portion and the peripheral portion,
wherein the inclined portion includes a first inclined portion and a second inclined portion, and
wherein the notch pattern is disposed to at least partially overlap the second inclined portion.

21. The display device of claim 20, wherein the inclined portion of the concave portion further includes a sub flat portion disposed between the first inclined portion and the second inclined portion, and
wherein the notch pattern is disposed to at least partially overlap a point where the sub flat portion and the second inclined portion contact each other.

22. The display device of claim 21, wherein in a cross-sectional shape of the notch pattern, a start point of the notch pattern is disposed closer to the flat portion of the concave portion than a point where the sub flat portion and the second inclined portion contact each other.
